(19) United States
(12) Patent Application Publication
(10) Pub. No.: US 2023/0361134 A1
(43) Pub. Date: Nov. 9, 2023

(54) METHOD FOR FABRICATING A DRIVING CIRCUIT BOARD

(71) Applicant: Shenzhen China Star Optoelectronics Semiconductor Display Technology Co., Ltd., Shenzhen (CN)

(72) Inventor: Chuanbao LUO, Shenzhen (CN)

(73) Assignee: Shenzhen China Star Optoelectronics Semiconductor Display Technology Co., Ltd., Shenzhen (CN)

(21) Appl. No.: 18/354,321

(22) Filed: Jul. 18, 2023

Related U.S. Application Data
(62) Division of application No. 15/734,492, filed on Dec. 2, 2020.

(30) Foreign Application Priority Data
Oct. 16, 2020 (CN) 202011108573.8

(51) Int. Cl. H01L 27/12

(52) U.S. Cl. CPC H01L 27/1288; H01L 27/124; H01L 25/167

(57) ABSTRACT

A method for fabricating a driving circuit board is provided, including: sequentially forming a first metal layer and a first protective layer on a substrate, wherein the first metal layer comprises a gate layer of a thin film transistor of the driving circuit board, and a first terminal and a second terminal disposed on opposite sides of the thin film transistor; sequentially forming a second metal layer and a third metal layer on the first protective layer, wherein the second metal layer comprises a source/drain layer of the thin film transistor and a connecting terminal disposed on the second terminal; and forming the third metal layer into a second protective layer by a first predetermined process.

### CROSS-REFERENCE TO RELATED APPLICATIONS

This application is a divisional application of U.S. patent application Ser. No. 15/734,492, filed on Dec. 2, 2020, which is a US national phase application based upon an International Application No. PCT/CN2020/124478, filed on Oct. 28, 2020, which claims priority to Chinese Patent Application No. 202011108573.8, filed on Oct. 16, 2020. The disclosures of the aforementioned applications are incorporated herein by reference in their entireties.

### FIELD OF INVENTION

The present disclosure relates to the field of display, and particularly to a driving circuit board and a method for fabricating the same.

### BACKGROUND

As people's requirements for display devices increase, optimization of back plates of backlight modules of the display devices is an important development direction.

A manufacturing process of a driving circuit board of a backlight module of a current display device is complicated and requires 7 photomasks, and its high-temperature manufacturing process easily causes oxidation of metal layers in the driving circuit board, thereby affecting product quality.

Therefore, there is an urgent need for a new driving circuit board and a method for fabricating the same to solve the above technical problem.

### SUMMARY OF DISCLOSURE

The present disclosure provides a driving circuit board and a method for fabricating the same to solve the problem that a manufacturing process of a driving circuit board of a backlight module of a current display device is complicated, thereby affecting product quality.

The present disclosure provides a driving circuit board. The driving circuit board comprises a substrate, a thin film transistor disposed on the substrate, and a first terminal and a second terminal disposed on opposite sides of the thin film transistor. One or more of a metal layer of the first terminal and a metal layer of the second terminal are disposed on a same layer as a gate layer or a source/drain layer of the thin film transistor.

In an embodiment, the metal layer of the first terminal and the metal layer of the second terminal are disposed on the same layer as the gate layer.

In an embodiment, the driving circuit board further comprises a first protective layer disposed on the gate layer, the first terminal, and the second terminal. The first protective layer is made of metal oxide.

In an embodiment, the driving circuit board further comprises a connecting terminal disposed on the second terminal. The connecting terminal is electrically connected to the second terminal through at least one first opening between the connecting terminal and the second terminal. The first opening is located in a portion of the first protective layer corresponding to the second terminal.

In an embodiment, the driving circuit board further comprises a light source corresponding to the second terminal and electrically connected to the second terminal through the first opening.

In an embodiment, the driving circuit board further comprises a second protective layer disposed on one or more of the source/drain layer and the connecting terminal. The second protective layer is made of one or more of molybdenum, titanium, nickel, and alloys thereof.

In an embodiment, the connecting terminal is electrically connected to the light source through at least one second opening between the connecting terminal and the light source. The second opening is located in a portion of the second protective layer corresponding to the connecting terminal.

In an embodiment, a first angle formed by a first side surface of the first protective layer and the substrate is less than or equal to 90 degrees.

In an embodiment, a second angle formed by a second side surface of the second protective layer and the substrate is less than or equal to 90 degrees.

In an embodiment, a first surface of the first protective layer in contact with the connecting terminal is provided with a plurality of first protrusions or a plurality of first concaves. The first protective layer is fitted with the connecting terminal through the first protrusions or the first concaves.

In an embodiment, the first protective layer is made of one or more of indium tin oxide and indium zinc oxide.

In an embodiment, the first protective layer has a thickness of 600 angstroms to 1800 angstroms.

In an embodiment, a third angle formed by the substrate and a third side surface of the first terminal, the gate layer, the source/drain layer, or the second terminal is greater than 30 degrees and less than 75 degrees.

The present disclosure further provides a method for fabricating a driving circuit board. The method comprises:
sequentially forming a first metal layer and a first protective layer on a substrate, wherein the first metal layer comprises a gate layer of a thin film transistor of the driving circuit board, and a first terminal and a second terminal disposed on opposite sides of the thin film transistor;
sequentially forming a second metal layer and a third metal layer on the first protective layer, wherein the second metal layer comprises a source/drain layer of the thin film transistor and a connecting terminal disposed on the second terminal; and
forming the third metal layer into a second protective layer by a first predetermined process.

In an embodiment, the first metal layer has a thickness of 4000 angstroms to 9600 angstroms.

In an embodiment, the step of sequentially forming the first metal layer and the first protective layer on the substrate comprises:
sequentially forming a first metal material layer and a first metal oxide layer on the substrate; and
patterning the first metal material layer and the first metal oxide layer to form the first metal layer and the first protective layer.

In an embodiment, the step of sequentially forming the second metal layer and the third metal layer on the first protective layer comprises:
forming a first insulator layer on the first protective layer;
forming an active layer on the gate layer;
sequentially forming the second metal layer and the third metal layer on the active layer.

In an embodiment, the step of forming the third metal layer into the second protective layer by the first predetermined process comprises:
removing a portion of the third metal layer corresponding to the connecting terminal to form the second protective layer.

In an embodiment, the portion of the third metal layer corresponding to the connecting terminal is removed by dry etching with plasma at a first power and a first ratio of fluorine to oxygen.

In an embodiment, the first power is 10.4 kW to 26.4 kW, and the first ratio of fluorine to oxygen is 2.4:1 to 7.2:1.

In a driving circuit board of the present disclosure, one or more of a metal layer of a first terminal and a metal layer of a second terminal are disposed on a same layer as a gate layer or a source/drain layer, thereby reducing a number of photomasks used in a manufacturing process of the driving circuit board, simplifying the manufacturing process, saving product manufacturing costs, and improving product yield.

### BRIEF DESCRIPTION OF DRAWINGS

Specific implementation of the present disclosure will be described in detail below in conjunction with accompanying drawings to make technical solutions and beneficial effects of the present disclosure obvious.

FIG. 1 is a schematic structural diagram of a first type of a driving circuit board according to an embodiment of the present disclosure.

FIG. 2 is a schematic structural diagram of a second type of a driving circuit board according to an embodiment of the present disclosure.

FIG. 3 is a schematic structural diagram of a third type of a driving circuit board according to an embodiment of the present disclosure.

FIG. 4 is a flowchart of a method for fabricating a driving circuit board according to an embodiment of the present disclosure.

FIG. 5a to FIG. 5g are schematic diagrams of the method for fabricating the driving circuit board according to an embodiment of the present disclosure.

### DETAILED DESCRIPTION

The present disclosure provides a driving circuit board and a method for fabricating the same. In order to make purposes, technical solutions, and effects of the present invention clearer and more definite, the present invention will be further described in detail below with reference to accompanying drawings and embodiments. It should be understood that specific embodiments described herein are only used to explain the present invention, not used to limit the present invention.

In order to solve the problem that a manufacturing process of a driving circuit board of a backlight module of a current display device is complicated and product quality is affected, the present disclosure provides a driving circuit board and a method for fabricating the same.

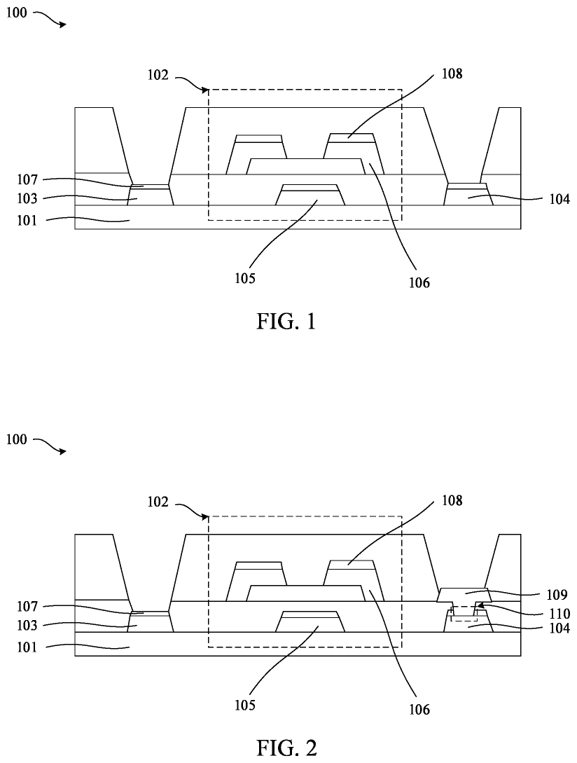

Please refer to FIG. 1 to FIG. 3, a driving circuit board 100 comprises a substrate 101, a thin film transistor 102 disposed on the substrate 101, and a first terminal 103 and a second terminal 104 disposed on opposite sides of the thin film transistor 102.

One or more of a metal layer of the first terminal 103 and a metal layer of the second terminal 104 are disposed on a same layer as a gate layer 105 or a source/drain layer 106 of the thin film transistor 102.

In this embodiment, the thin film transistor 102 may be a bottom-gate thin film transistor, a top-gate thin film transistor, or other types of thin film transistors, which is not specifically limited herein.

In this embodiment, the driving circuit board 100 may be used in a backlight module of a display device.

In this embodiment, when the metal layer of the first terminal 103 or the metal layer of the second terminal 104 is disposed on the same layer as the gate layer 105, the metal layer may be made of one or more of molybdenum or molybdenum-copper alloy.

In this embodiment, when the metal layer of the first terminal 103 or the metal layer of the second terminal 104 is disposed on the same layer as the source/drain layer 106, the metal layer may be made of one or more of molybdenum, titanium, copper, or alloys thereof, such as molybdenum-copper alloy, and molybdenum-titanium-copper alloy.

In this embodiment, the first terminal 103 may be configured for electrical connection between the driving circuit board 100 and other components in the display device, such as a flip chip film.

In this embodiment, the second terminal 104 may be configured to electrically connect a light source.

In this embodiment, the driving circuit board 100 further comprises a gate insulating layer and an active layer that are disposed between the gate layer 105 and the source/drain layer 106.

In this embodiment, the gate insulating layer may be made of one or more of silicon oxide, silicon nitride, silicon oxynitride, aluminum oxide, and aluminum nitride. The gate insulating layer may be made of a single material, such as silicon oxide and aluminum nitride. The gate insulating layer may also be made by stacking multiple materials, for example, by stacking silicon oxide and silicon nitride, by stacking silicon oxide, silicon nitride, and silicon oxynitride, or by stacking silicon oxide, silicon nitride, and aluminum oxide. When the gate insulating layer is made by stacking multiple materials, a stacking manner of different materials is not specifically limited herein.

In this embodiment, the driving circuit board 100 further comprises a passivation layer disposed on the source/drain layer 106.

In this embodiment, the passivation layer may be made of one or more of silicon oxide, silicon nitride, aluminum oxide, and aluminum nitride. The passivation layer may be made of a single material, such as silicon oxide and aluminum nitride. The passivation layer may also be made by stacking multiple materials, for example, by stacking silicon oxide and silicon nitride, or by stacking silicon oxide, silicon nitride, and aluminum oxide. A stacking manner of different materials is not specifically limited herein.

In the present invention, one or more of the metal layer of the first terminal 103 and the metal layer of the second terminal 104 are disposed on the same layer as the gate layer 105 or the source/drain layer 106, thereby reducing a number of photomasks used in a manufacturing process of the driving circuit board 100, simplifying the manufacturing process, saving product manufacturing costs, and improving product yield.

Technical solutions of the present disclosure will now be described in conjunction with specific embodiments.

### Example 1

Please refer to FIG. 1, each of the first terminal 103 and the second terminal 104 comprises the metal layer disposed on the same layer as the gate layer 105.

In this embodiment, the driving circuit board 100 further comprises a first protective layer 107 disposed on the gate layer 105, the first terminal 103, and the second terminal 104.

The first protective layer 107 is made of metal oxide.

In this embodiment, the metal layer of the first terminal 103 and the metal layer of the second terminal 104 may be formed with a same material and in a same process as the gate layer 105.

In this embodiment, the first terminal 103 and the second terminal 104 may be made of only one metal layer 25.

In this embodiment, the first protective layer 107, the gate layer 105, the first terminal 103, and the second terminal 104 may be formed in a same process.

In this embodiment, the first protective layer 107 may be made of one or more of indium tin oxide, indium zinc oxide, and other metal oxides.

The first protective layer 107 is configured to prevent metal materials of the gate layer 105, the first terminal 103, and the second terminal 104, such as copper, from being oxidized during a high-temperature process in subsequent processes of the driving circuit board 100, or to prevent thermal diffusion of ions. The thermal diffusion of ions causes metal ions to enter other layers, such as the gate insulating layer, thereby affecting performance of the driving circuit board 100 and quality of a product using the driving circuit board 100.

In this embodiment, the metal layer of the first terminal 103 and the metal layer of the second terminal 104 are disposed on the same layer as the gate layer 105, so that the metal layer of the first terminal 103 and the metal layer of the second terminal 104 can be formed with the same material and in the same process as the gate layer 105, thereby reducing a number of photomasks used in a manufacturing process of the driving circuit board 100, simplifying the manufacturing process, saving product manufacturing costs, and improving product yield.

### Example 2

Please refer to FIG. 2. This example is similar to Example 1, and differences are described below.

In this embodiment, the driving circuit board 100 further comprises a connecting terminal 109 disposed on the second terminal 104. The connecting terminal 109 is electrically connected to the second terminal 104 through at least one first opening 110 between the connecting terminal 109 and the second terminal 104. The first opening 110 is located in a portion of the first protective layer 107 corresponding to the second terminal 104.

In this embodiment, the connecting terminal 109 may be disposed on a same layer as the source/drain layer 106.

In this embodiment, the connecting terminal 109 and the source/drain layer 106 may be made of a same material and in a same process.

The connecting terminal 109 is electrically connected to the second terminal 104 through the first opening 110. The first opening 110 increases a contact area between the connecting terminal 109 and the first protective layer 107. This is beneficial to increase adhesion between the connecting terminal 109 and the first protective layer 107. And, this is beneficial to prevent the connecting terminal 109 from being separated from the first protective layer 107, which affects quality of the driving circuit board 100. In addition, the connecting terminal 109 can directly contact the second terminal 104 through the first opening 110, thereby reducing a resistance between the connecting terminal 109 and the second terminal 104. This is beneficial to reduce power consumption of the driving circuit board 100 during use.

In this embodiment, the connecting terminal 109 may be configured for electrical connection between the light source and the second terminal 104.

In an embodiment, a first surface of the first protective layer 107 in contact with the connecting terminal 109 is provided with a plurality of first protrusions and/or a plurality of first concaves.

The first protective layer 107 is fitted with the connecting terminal 109 through the first protrusions and/or the first concaves.

Fitting of the first protective layer 107 and the connecting terminal 109 is beneficial to increase the contact area between the connecting terminal 109 and the first protective layer 107, and improves the adhesion between the connecting terminal 109 and the first protective layer 107. This is beneficial to prevent the connecting terminal 109 from being separated from the first protective layer 107, which affects quality of the driving circuit board 100.

In this embodiment, the driving circuit board 100 further comprises the light source corresponding to the second terminal 104. The light source is electrically connected to the second terminal 104 through the first opening 110.

In this embodiment, the light source may be a light emitting diode.

In this embodiment, the light source is electrically connected to the second terminal 104 through a surface mount process.

The light source is electrically connected to the second terminal 104 through solder paste in the surface mount process. The first protective layer 107 is made of metal oxide, which has a weak bonding force with the solder paste. The first opening 110 allows the solder paste to directly contact the second terminal 104, which improves adhesion of the solder paste to the second terminal 104. This is beneficial to prevent the light source from being separated due to insufficient adhesion between the first protective layer 107 and the solder paste.

The connecting terminal 109 is made of a metal material, which is conducive to the adhesion of the solder paste. Therefore, the connecting terminal 109 also prevents the light source from being separated due to the insufficient adhesion between the first protective layer 107 and the solder paste.

In this embodiment, the connecting terminal 109 is electrically connected to the second terminal 104 through the first opening 110, which increases the adhesion between the connecting terminal 109 and the first protective layer 107 and is beneficial to prevent the connecting terminal 109 from being separated from the first protective layer 107. The light source is electrically connected to the second terminal 104 through the first opening 110, which is beneficial to prevent the light source from being separated due to insufficient adhesion between the first protective layer 107 and the solder paste.

### Example 3

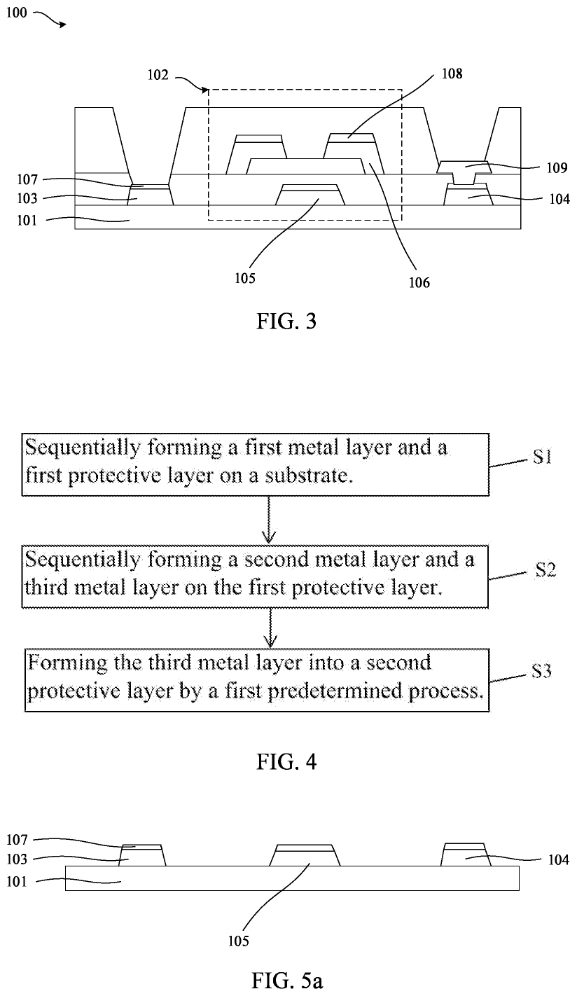

Please refer to FIG. 3. This example is similar to Example 1 and Example 2, and differences are described below.

The driving circuit board 100 further comprises a second protective layer 108 disposed on one or more of the source/drain layer 106 and the connecting terminal 109.

The second protective layer 108 is made of one or more of molybdenum, titanium, nickel, and alloys thereof, such as molybdenum-titanium alloy, titanium, and nickel.

In this embodiment, the second protective layer 108 may be formed in a same process as the source/drain layer 106 or/and the connecting terminal 109.

The second protective layer 108 is made of a high-temperature resistant and oxidation-resistant metal, and are configured to prevent metal materials of the source/drain layer 106 or/and the connecting terminal 109, such as copper, from being oxidized during a high-temperature process in subsequent processes of the driving circuit board 100, thereby preventing the performance of the driving circuit board 100 and the quality of the product using the driving circuit board 100 from being affected.

In this embodiment, the second protective layer 108 may be disposed on the source/drain layer 106.

In this embodiment, the second protective layer 108 may also be disposed on the source/drain layer 106 and the connecting terminal 109.

In this embodiment, the connecting terminal 109 is electrically connected to the light source through at least one second opening between the connecting terminal 109 and the light source. The second opening is located in a portion of the second protective layer 108 corresponding to the connecting terminal 109.

The light source is electrically connected to the connecting terminal 109 through solder paste in a surface mount process. A material of the second protective layer 108 has a weak bonding force with the solder paste, which is not conducive to adhesion of the solder paste. The second opening allows the solder paste to directly contact the connecting terminal 109, which improves the adhesion of the solder paste. This is beneficial to prevent the light source from being separated due to insufficient adhesion between the second protective layer 108 and the solder paste, thereby preventing product quality from being affected.

In this embodiment, the second protective layer 108 is beneficial to prevent the source/drain layer 106 or/and the connecting terminal 109 from being oxidized in the subsequent processes of the driving circuit board 100, thereby improving the product quality. In addition, the second protective layer 108 may be formed in the same process as the source/drain layer 106 or/and the connecting terminal 109, which avoids additional processes and saves process costs while improving the product quality.

In the above embodiments, a first angle formed by a first side surface of the first protective layer 107 and the substrate 101 is less than or equal to 90 degrees, and/or a second angle formed by a second side surface of the second protective layer 108 and the substrate 101 is less than or equal to 90 degrees. When the first angle is greater than 90 degrees, a side of the first protective layer 107 away from the substrate 101 forms an acute angle with the first side surface, so that the first protective layer 107 easily pierces other layers around the first protective layer 107, such as the gate insulating layer, and the performance of the driving circuit board 100 is affected. Similarly, when the second angle is greater than 90 degrees, a side of the second protective layer 108 away from the substrate 101 forms an acute angle with the second side surface, so that the second protective layer 108 easily pierces other layers around the second protective layer 108, such as the passivation layer, and the performance of the driving circuit board 100 is affected.

In the above embodiments, a third angle formed by the substrate 101 and a third side surface of the first terminal 103, the gate layer 105, the source/drain layer 106, or the second terminal 104 is greater than 30 degrees and less than 75 degrees, preferably 45 degrees to 60 degrees. When the third angle is less than 30 degrees, the third angle is too small, resulting in a significant delay in signal transmission of the driving circuit board 100. When the third angle is greater than 75 degrees, the third angle is too large, causing other layers on the layer forming the third angle to be broken during their formation, thereby affecting the product quality of the drive circuit board 100. When the third angle is between 45 degrees and 60 degrees, the signal transmission of the driving circuit board 100 will not be significantly delayed, and the other layers on the layer forming the third angle will not be broken during their formation.

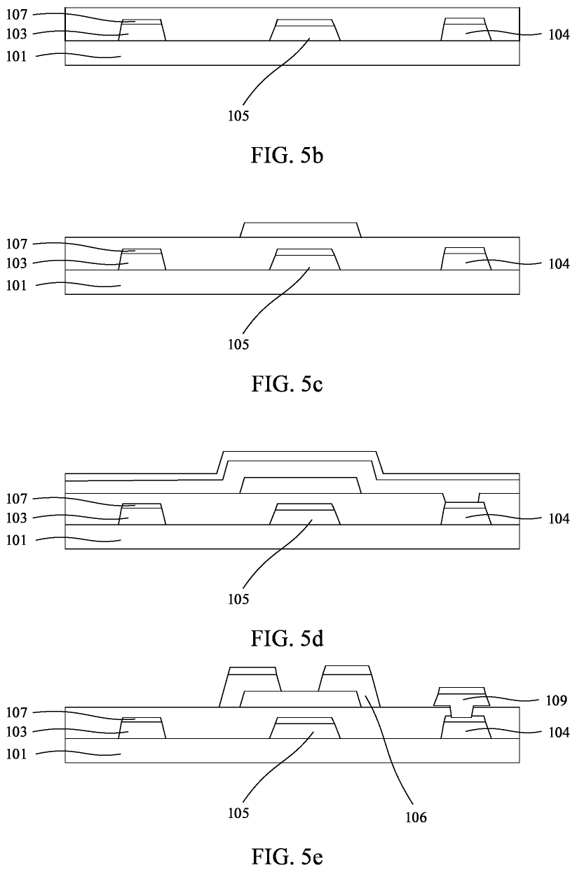

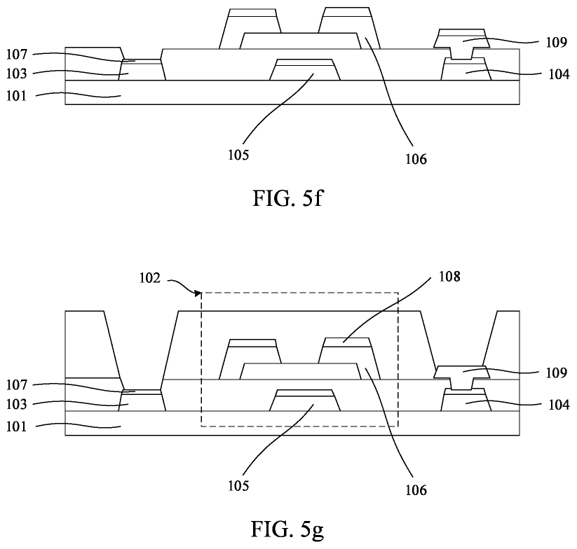

Please refer to FIG. 4 and FIG. 5a to FIG. 5g. The present disclosure further provides a method for fabricating a driving circuit board 100. The method comprises the following steps.

Please refer to FIG. 5a. S1: sequentially forming a first metal layer and a first protective layer 107 on a substrate 101.

In this embodiment, the first metal layer comprises a gate layer 105 of a thin film transistor 102 of the driving circuit board 100, and a first terminal 103 and a second terminal 104 disposed on opposite sides of the thin film transistor 102.

In this embodiment, step S1 comprises the following steps.

S11: sequentially forming a first metal material layer and a first metal oxide layer on the substrate 101.

In this embodiment, the first metal material layer and the first metal oxide layer may be formed by deposition, such as physical vapor sputtering deposition.

In this embodiment, the first metal material layer may be made of one or more of molybdenum or molybdenum-copper alloy.

In this embodiment, the first metal oxide layer may be made of one or more of indium tin oxide, indium zinc oxide, and other metal oxides.

S12: patterning the first metal material layer and the first metal oxide layer to form the first metal layer and the first protective layer 107.

In this embodiment, the first metal layer and the first protective layer 107 may be formed by wet etching.

In this embodiment, the first metal layer is formed by a first etching solution comprising hydrogen peroxide.

The first protective layer 107 is formed by a second etching solution comprising oxalic acid.

In this embodiment, the first metal layer may have a thickness of 4000 angstroms to 9600 angstroms, preferably 5000 to 8000 angstroms.

The first protective layer 107 may have a thickness of 600 angstroms to 1800 angstroms, preferably 750 to 1500 angstroms. When other layers are formed by etching in the subsequent processes, the first protective layer 107 is thinned by over-etching. When the thickness of the first protective layer 107 is less than 600 angstroms, the thickness of the first protective layer 107 is too thin to prevent the first metal layer from being thermally oxidized during a high-temperature manufacturing process, and to prevent ions in the first metal layer from thermally diffusing into other layers. When the thickness of the first protective layer 107 is greater than 1800 angstroms, the thickness of the first protective layer 107 is too thick, and a resistance of the first protective layer 107 increases significantly. This increases power consumption of a display device using the driving circuit board 100. When the thickness of the first protective layer 107 is 750 angstroms to 1500 angstroms, the first protective layer 107 is not too thin to completely protect the first metal layer during a high-temperature manufacturing process, and is not too thick so that the power consumption of the display device using the driving circuit board 100 does not increase.

Please refer to FIG. 5b to FIG. 5e. S2: sequentially forming a second metal layer and a third metal layer on the first protective layer 107.

In this embodiment, the second metal layer comprises a source/drain layer 106 of the thin film transistor 102 and a connecting terminal 109 disposed on the second terminal 104.

In this embodiment, the second metal layer may have a thickness of 4000 angstroms to 9600 angstroms, preferably 5000 to 8000 angstroms.

In this embodiment, step S2 comprises the following steps.

S21: forming a first insulator layer on the first protective layer 107.

S22: forming an active layer on the gate layer 105.

In this embodiment, step S22 comprises the following steps.

S22a: forming a semiconductor layer on the gate layer 105.

In this embodiment, the semiconductor layer is made of one or more of indium gallium zinc oxide, indium gallium zinc tin oxide, indium zinc oxide, and indium gallium tin oxide.

S22b: forming the semiconductor layer into an active layer by a second predetermined process.

In this embodiment, the semiconductor layer is formed into the active layer by thermal annealing and photolithography.

An etching solution used for photolithography may comprise oxalic acid.

S23: sequentially forming the second metal layer and the third metal layer on the active layer.

In this embodiment, the second metal layer may be made of one or more of molybdenum, titanium, copper, or alloys thereof, such as molybdenum-copper alloy, and molybdenum-titanium-copper alloy.

The third metal layer may be made of one or more of molybdenum, titanium, nickel, and alloys thereof, such as molybdenum-titanium alloy, titanium, and nickel.

In this embodiment, step S23 comprises the following steps.

S23a: forming the first insulator layer into a first insulating layer.

S23b: sequentially forming a second metal material layer and a third metal material layer on the active layer.

In this embodiment, the first metal material layer and the third metal material layer are formed on the active layer by physical vapor deposition.

S23c: forming the second metal material layer and the third metal material layer into the second metal layer and the third metal layer by a third predetermined process.

In this embodiment, the second metal layer and the third metal layer may be formed by wet etching.

In this embodiment, the second metal layer and the third metal layer are formed by a fourth etching solution comprising hydrogen peroxide.

Please refer to FIG. 5f and FIG. 5g. S3: forming the third metal layer into a second protective layer 108 by a first predetermined process.

In this embodiment, step S3 comprises the following step.

S31: removing a portion of the third metal layer corresponding to the connecting terminal 109 to form the second protective layer 108.

In this embodiment, step S31 comprises the following steps.

S31a: forming the first insulating layer into a gate insulating layer by a fifth preset process.

S31b: forming a second insulator layer on the third metal layer.

S31c: forming the second insulator layer into a passivation layer by a fourth predetermined process.

In this embodiment, the passivation layer is provided with a third opening corresponding to the first terminal 103 and a fourth opening corresponding to the second terminal 104.

In this embodiment, the gate insulating layer is provided with a fifth opening located between the first terminal 103 and the third opening, and a sixth opening located between the fourth opening and the second terminal 104.

The fourth opening exposes the portion of the third metal layer corresponding to the connecting terminal 109.

In this embodiment, the gate insulating layer and the passivation layer may be formed by dry etching.

In this embodiment, the gate insulating layer and the passivation layer may be formed by dry etching with a strong oxidizing gas comprising fluorine.

In this embodiment, the gate insulating layer may be made of one or more of silicon oxide, silicon nitride, silicon oxynitride, aluminum oxide, and aluminum nitride. The gate insulating layer may be made of a single material, such as silicon oxide and aluminum nitride. The gate insulating layer may also be made by stacking multiple materials, for example, by stacking silicon oxide and silicon nitride, by stacking silicon oxide, silicon nitride, and silicon oxynitride, or by stacking silicon oxide, silicon nitride, and aluminum oxide. When the gate insulating layer is made by stacking multiple materials, a stacking manner of different materials is not specifically limited herein.

In this embodiment, the passivation layer may be made of one or more of silicon oxide, silicon nitride, aluminum oxide, and aluminum nitride. The passivation layer may be made of a single material, such as silicon oxide and aluminum nitride. The passivation layer may also be made by stacking multiple materials, for example, by stacking silicon oxide and silicon nitride, or by stacking silicon oxide, silicon nitride, and aluminum oxide. A stacking manner of different materials is not specifically limited herein.

S31d: removing the portion of the third metal layer corresponding to the connecting terminal 109 by etching to form the second protective layer 108.

In this embodiment, the second protective layer 108 is formed by dry etching the third metal layer.

In this embodiment, the second protective layer 108 is formed by dry etching with plasma at a first power and a first ratio of fluorine to oxygen.

The first power may be 10.4 kW to 26.4 kW, preferably 13 kW to 20 kW. When the first power is less than 10.4 kW, the first power is too small. Therefore, a time for etching the portion of the third metal layer corresponding to the connecting terminal 109 is too long, which is not conducive to improvement of process efficiency. When the first power does not exceed 26.4 kW, the first power is sufficient to meet requirements for etching the portion of the third metal layer corresponding to the connecting terminal 109. Therefore, the first power does not need to exceed 26.4 kW. When the first power is 13 kW to 20 kW, it can be ensured that the portion of the third metal layer corresponding to the connecting terminal 109 is etched quickly and completely.

The first ratio of fluorine to oxygen is 2.4:1 to 7.2:1, preferably 3:1 to 6:1. When the first ratio of fluorine to oxygen is less than 2.4:1 or greater than 7.2:1, a fluorine content and an oxygen content of the plasma are insufficient, which affects an oxidizing property of the plasma and is not conducive to etching the portion of the third metal layer corresponding to the connecting terminal 109. When the first ratio of fluorine to oxygen is 3:1 to 6:1, the fluorine content and the oxygen content of the plasma are appropriate. This ensures the strong oxidizing property of the plasma, so that the portion of the third metal layer corresponding to the connecting terminal 109 is etched quickly and completely.

In this embodiment, when the driving circuit board 100 is applied to a backlight module of a display device, a light source is mounted on the driving circuit board 100 through a surface mount process.

In the method for fabricating the driving circuit board 100 provided by the present disclosure, one or more of the metal layer of the first terminal 103 and the metal layer of the second terminal 104 are disposed on the same layer as the gate layer 105 or the source/drain layer 106, thereby reducing the number of the photomasks used in the manufacturing process of the driving circuit board 100, simplifying the manufacturing process, saving the product manufacturing costs, and improving the product yield.

The present disclosure provides a driving circuit board and a method for fabricating the same. The driving circuit board comprises a substrate, a thin film transistor disposed on the substrate, and a first terminal and a second terminal disposed on opposite sides of the thin film transistor. One or more of a metal layer of the first terminal and a metal layer of the second terminal are disposed on a same layer as a gate layer or a source/drain layer of the thin film transistor, thereby reducing a number of photomasks used in a manufacturing process of the driving circuit board, saving product manufacturing costs, and improving product yield. In a driving circuit board of the present disclosure, one or more of a metal layer of a first terminal and a metal layer of a second terminal are disposed on a same layer as a gate layer or a source/drain layer, thereby reducing a number of photomasks used in a manufacturing process of the driving circuit board, simplifying the manufacturing process, saving product manufacturing costs, and improving product yield.

It should be understood that those skilled in the art may make equivalent replacements or changes based on the technical solutions and inventive concepts of the present application, and all such changes or replacements shall fall within the scope of the claims of the present application.

What is claimed is:

1. A method for fabricating a driving circuit board, comprising:
sequentially forming a first metal layer and a first protective layer on a substrate, wherein the first metal layer comprises a gate layer of a thin film transistor of the driving circuit board, and a first terminal and a second terminal disposed on opposite sides of the thin film transistor;
sequentially forming a second metal layer and a third metal layer on the first protective layer, wherein the second metal layer comprises a source/drain layer of the thin film transistor and a connecting terminal disposed on the second terminal; and
forming the third metal layer into a second protective layer by a first predetermined process.

2. The method for fabricating the driving circuit board according to claim 1, wherein the first metal layer has a thickness of 4000 angstroms to 9600 angstroms.

3. The method for fabricating the driving circuit board according to claim 1, wherein sequentially forming the first metal layer and the first protective layer on the substrate comprises:
sequentially forming a first metal material layer and a first metal oxide layer on the substrate; and
patterning the first metal material layer and the first metal oxide layer to form the first metal layer and the first protective layer.

4. The method for fabricating the driving circuit board according to claim 1, wherein sequentially forming the second metal layer and the third metal layer on the first protective layer comprises:
forming a first insulator layer on the first protective layer;
forming an active layer on the gate layer; and
sequentially forming the second metal layer and the third metal layer on the active layer.

5. The method for fabricating the driving circuit board according to claim 1, wherein forming the third metal layer into the second protective layer by the first predetermined process comprises:
removing a portion of the third metal layer corresponding to the connecting terminal to form the second protective layer.

6. The method for fabricating the driving circuit board according to claim 5, wherein the portion of the third metal layer corresponding to the connecting terminal is removed by dry etching with plasma at a first power and a first ratio of fluorine to oxygen.

7. The method for fabricating the driving circuit board according to claim 6, wherein the first power is 10.4 kW to 26.4 kW, and the first ratio of fluorine to oxygen is 2.4:1 to 7.2:1.
